(19) United States
(12) Patent Application Publication
(10) Pub. No.: US 2025/0040199 A1
(43) Pub. Date: Jan. 30, 2025

(54) SHARED SOURCE/DRAIN CONTACT FOR STACKED TRANSISTORS

(71) Applicant: INTERNATIONAL BUSINESS MACHINES CORPORATION, ARMONK, NY (US)

(72) Inventors: Ruilong Xie, Niskayuna, NY (US); Brent A. Anderson, Jericho, VT (US); Albert M. Chu, Nashua, NH (US); Junli Wang, Slingerlands, NY (US); Jay William Strane, Wappingers Falls, NY (US)

(21) Appl. No.: 18/359,922

(22) Filed: Jul. 27, 2023

(51) Int. Cl. H01L 29/06; H01L 21/8234; H01L 27/088; H01L 29/08; H01L 29/423; H01L 29/66; H01L 29/775; H01L 29/786

(52) U.S. Cl. CPC H01L 29/0673; H01L 21/823418; H01L 27/088; H01L 29/0847; H01L 29/42392; H01L 29/66439; H01L 29/66545; H01L 29/775; H01L 29/78696

(57) ABSTRACT

Embodiments of present invention provide a semiconductor structure. The semiconductor structure includes a first transistor having a first source/drain (S/D) region; a second transistor having a second S/D region, the second transistor being stacked on top of the first transistor; and a first S/D contact shared by the first S/D region of the first transistor and the second S/D region of the second transistor, where the first S/D contact has a first portion and a second portion, the first portion being in direct contact with a top surface of the first S/D region of the first transistor and in direct contact with a bottom surface of the second S/D region, and the second portion being in direct contact with an inner sidewall of the second S/D region of the second transistor. A method of manufacturing the semiconductor structure is also provided.

### BACKGROUND

The present application relates to manufacturing of semiconductor integrated circuits. More particularly, it relates to a shared source/drain contact for vertically stacked transistors and a method of forming the same.

As semiconductor industry moves towards smaller node, for example 7-nm node and beyond, field-effect-transistors (FETs) are aggressively scaled in order to fit into the reduced footprint or real estate, which is often dictated by the node size, with increased device density. For example, one transistor may be vertically stacked on top of another transistor thereby doubling the density of transistors in a given footprint.

In some applications such as, for example, in a static random-access-memory (SRAM) configuration, the two stacked transistors may share a common source/drain contact. However, issues and/or concerns have been identified in current approaches of forming a shared source/drain contact. For instance, in one example, some shared source/drain contact may have a small bottom epi contact while top epi contact has to rely on sidewall silicide, raising concerns on reliability of the top epi contact. In another example, the bottom epi contact may utilize only half of the size that is available from the bottom epi resulting in poor contact resistance.

### SUMMARY

Embodiments of present invention provide a semiconductor structure. The semiconductor structure includes a first transistor having a first source/drain (S/D) region; a second transistor having a second S/D region, the second transistor being stacked on top of the first transistor; and a first S/D contact shared by the first S/D region of the first transistor and the second S/D region of the second transistor, where the first S/D contact has a first portion and a second portion, the first portion being in direct contact with a top surface of the first S/D region of the first transistor and in direct contact with a bottom surface of the second S/D region. Through increased contact areas by directly contacting both the bottom surface of the second S/D region of the second S/D region and the top surface of the first S/D region of the first S/D region, the first S/D contact provides a much reduced contact resistance. In the meantime, the second portion is in direct contact with an inner sidewall of the second S/D region of the second transistor, thereby having a more reliable contact with the second S/D region of the second transistor.

According to one embodiment, the semiconductor structure further includes a trench anchor directly on top of the first S/D region of the first transistor, where the first portion of the first S/D contact saddles on the trench anchor to be in contact with a top surface and sidewall surfaces of the trench anchor. The trench anchor of epitaxial SiGe provides additional contact areas between the first S/D contact and the first S/D region of the first transistor, thereby further helps reduce contact resistance.

In one embodiment, the trench anchor includes epitaxially grown silicon-germanium (SiGe) and is partially embedded in the first S/D region of the first transistor.

In another embodiment, the second portion of the first S/D contact is directly on top of a portion of the first portion of the first S/D contact.

In yet another embodiment, the second S/D region of the second transistor includes an opening extending from a top surface thereof to the bottom surface thereof, the opening has the inner sidewall, and the inner sidewall is in direct contact with the second portion of the first S/D contact.

In one embodiment, the first and the second transistor are a first and a second nanosheet transistor, and the semiconductor structure further includes a dielectric insulating layer separating the first transistor from the second transistor.

In one embodiment, the top surface of the first S/D region of the first transistor has a V-shape and a bottom surface of the first S/D region of the first transistor has an inverted V-shape.

According to one embodiment, the semiconductor structure further includes a second S/D contact contacting a top surface of a fourth S/D region of the second transistor, and a first backside S/D contact contacting a bottom surface of a third S/D region of the first transistor.

Embodiments of present invention also provide a method of forming a semiconductor structure. The method includes forming a first source/drain (S/D) region of a first transistor on a substrate; forming a first interlevel dielectric (ILD) layer on top of the first S/D region; forming a second S/D region of a second transistor on top of the first ILD layer; creating an opening in the second S/D region of the second transistor and in the first ILD layer to expose a top surface of the first S/D region of the first transistor; removing the first ILD layer via the opening thereby horizontally expanding a portion of the opening between the first S/D region of the first transistor and the second S/D region of the second transistor to expose the top surface of the first S/D region and expose a bottom surface of the second S/D region; and filling the opening with a conductive material to form a first S/D contact, the first S/D contact being shared by the first S/D region of the first transistor and the second S/D region of the second transistor.

According to one embodiment, the method further includes, before removing the first ILD layer via the opening, forming a trench anchor in the opening by epitaxially growing the trench anchor from the exposed top surface of the first S/D region of the first transistor.

In one embodiment, the trench anchor has a height below the bottom surface of the second S/D region of the second transistor.

In another embodiment, the first S/D contact has a first portion and a second portion with the second portion being directly on top of the first portion, the first portion of the first S/D contact fills the expanded portion of the opening and saddles on the trench anchor.

In yet another embodiment, forming the first S/D region includes epitaxially growing the first S/D region to have the top surface formed in a V-shape.

According to another embodiment, the method further includes forming a second S/D contact contacting a top surface of a fourth S/D region of the second transistor and forming a first backside S/D contact contacting a bottom surface of a third S/D region of the first transistor.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C to FIGS. 20A, 20B, and 20C are demonstrative illustrations of different cross-sectional views and/or simplified top views of a semiconductor structure in various steps of manufacturing thereof according to embodiments of present invention; and

FIG. 21 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

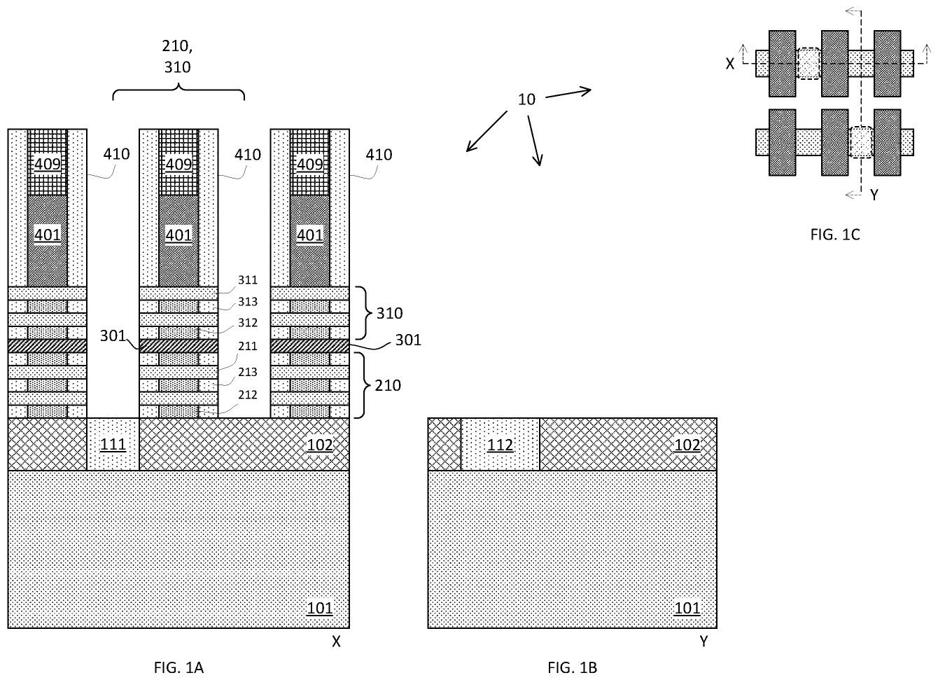

FIGS. 1A and 1B are demonstrative illustrations of different cross-sectional views and FIG. 1C is a simplified top view of a semiconductor structure in a step of manufacturing thereof according to one embodiment of present invention. More specifically, FIG. 1A illustrates a cross-sectional view of the semiconductor structure along a dashed line X as illustrated in FIG. 1C. In other words, the cross-sectional view in FIG. 1A is made across the gate in a direction along the length of the gate. FIG. 1B illustrates a cross-sectional view of the semiconductor structure along a dashed line Y as illustrated in FIG. 1C. In other words, the cross-sectional view in FIG. 1B is made across the S/D region in a direction along the width of the gate. FIG. 1C may selectively illustrate key elements such as, for example, nanosheets, gates, S/D regions, and elements that are yet to be formed or are covered in view by other elements. On the other hand, elements such as dielectric cap layer, sidewall spacers, etc. may not necessarily be illustrated in order to avoid overcrowding the drawing, and to the extent that their omitting from FIG. 1C does not hinder the description of embodiments of present invention, even though some of these elements do exist as well.

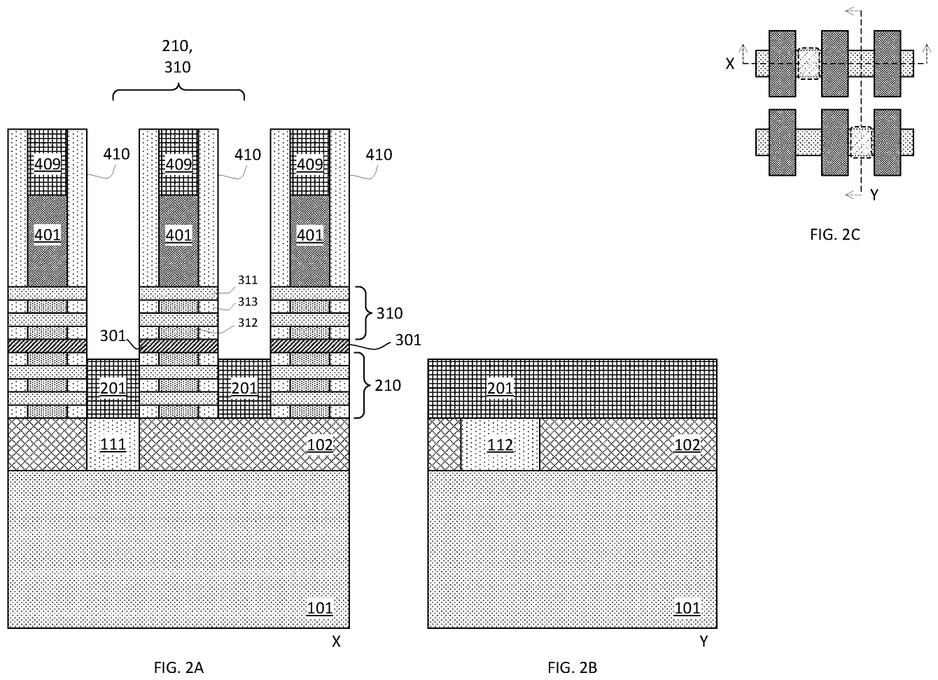

Similarly, FIGS. 2A, 2B, and 2C to FIGS. 20A, 20B, and 20C illustrate cross-sectional views and simplified top views of the semiconductor structure, at various manufacturing stages, in a manner corresponding to FIGS. 1A, 1B, and 1C.

Embodiments of present invention provide forming a semiconductor structure 10 that is demonstratively illustrated to include multiple sets of stacked nanosheet transistors. However, embodiments of present invention are not limited in this aspect and may be applied to other types of transistors and/or active devices. Particularly, the semiconductor structure 10 may include a semiconductor substrate 101 and an insulating layer such as an oxide layer 102 on top of the substrate 101. One or more sets of stacked nanosheet transistors may be formed on top of the oxide layer 102. For example, one of the one or more sets of stacked nanosheet transistors may include a bottom nanosheet transistor 210 and a top nanosheet transistor 310. The bottom nanosheet transistor 210 may include a set of nanosheets 211, which may be silicon (Si) nanosheets, being separated by a set of sacrificial sheets 212, which may be silicon-germanium (SiGe) nanosheets. Inner spacers 213 of dielectric material such as, for example, silicon-nitride (SiN) or silicon-oxide (SiO₂) may be formed at indentations created at the set of sacrificial sheets 212. Similarly, the top nanosheet transistor 310 may include a set of nanosheets 311 of, for example, Si nanosheets being separated by a set of sacrificial sheets 312 of, for example, SiGe nanosheets. Inner spacers 313 of dielectric material such as, for example, SiN or SiO₂ may be formed at indentations created at the set of sacrificial sheets 312. The bottom nanosheet transistor 210 may be insulated or separated from the top nanosheet transistor 310 by a spacer layer such as, for example, a middle dielectric isolation (MDI) layer 301.

One or more sacrificial gate structures may be formed on top of the one or more sets of nanosheet transistor structures. For example, one sacrificial gate structure may include a sacrificial gate 401 that may be patterned through a directional and/or selective etching process and by applying a hard mask 409 formed on top thereof during the etching process. Sidewall spacers 410 may be formed at sidewalls of the sacrificial gate 401. The one or more sacrificial gate structures may subsequently be used in an etching or recessing process that patterns a stack of raw nanosheets into one or more sets of stacked nanosheets for forming the one or more sets of stacked nanosheet transistors.

Embodiments of present invention further provide etching the oxide layer 102 through the openings between the sacrificial gate structures to form one or more placeholders for forming backside contacts later during a backside processing step. For example, a first and a second placeholder 111 and 112 may be formed to be embedded in the oxide layer 102 through, for example, a selective etching process followed by an epitaxial growth process. In one embodiment, the first and the second placeholders 111 and 112 may be SiGe epitaxially grown from the semiconductor substrate 101 which may be a Si substrate.

FIGS. 2A and 2B are demonstrative illustrations of different cross-sectional views and FIG. 2C is a simplified top view of a semiconductor structure in a step of manufacturing thereof according to one embodiment of present invention. More particularly, following the step illustrated in FIGS. 1A, 1B, and 1C, embodiments of present invention provide forming a sacrificial layer 201 to protect sidewalls of the set of nanosheets 211 of the bottom nanosheet transistor 210. For example, an organic planarization layer (OPL) may be formed in the openings between, and above, the one or more sacrificial gate structures. After that, the OPL between the sacrificial gate structures may be recessed. For example, the OPL may be recessed down to below the level of the MDI layer 301 such that sidewalls of the set of nanosheets 311 of the top nanosheet transistor 310 may be exposed. In the meantime, the remaining OPL may form the sacrificial layer 201 covering sidewalls of the set of nanosheets 211 of the bottom nanosheet transistor 210.

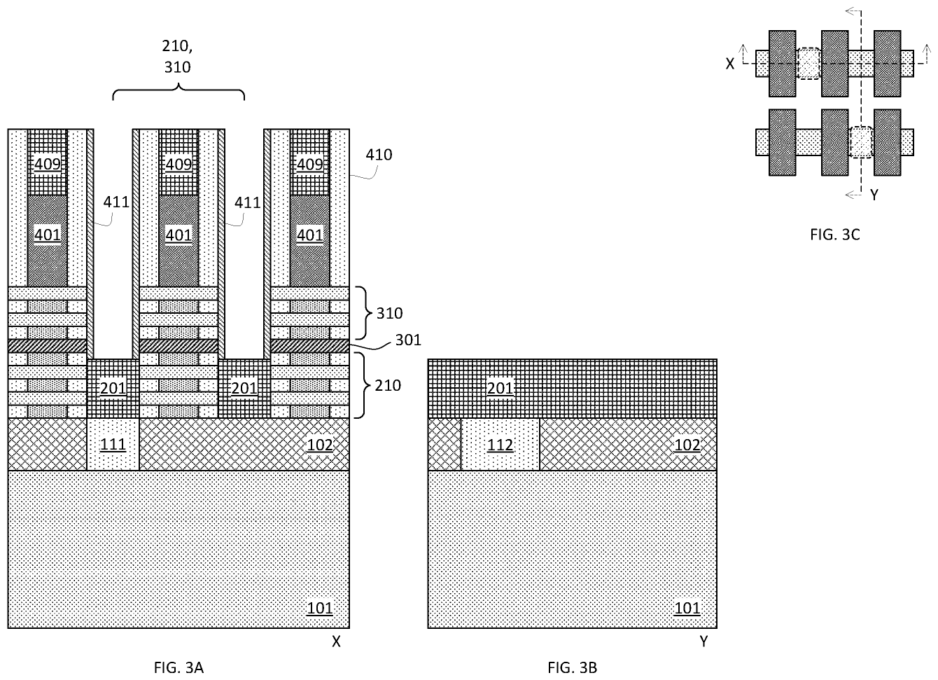

FIGS. 3A and 3B are demonstrative illustrations of different cross-sectional views and FIG. 3C is a simplified top view of a semiconductor structure in a step of manufacturing thereof according to one embodiment of present invention. More particularly, following the step illustrated in FIGS. 2A, 2B, and 2C, embodiments of present invention provide forming a protective liner 411 lining sidewalls of the set of nanosheets 311 of the top nanosheet transistor 310 and the sacrificial gate structure on top thereof. The protective liner 411 may be formed by, for example, depositing a conformal layer of protective material covering the semiconductor structure 10 and subsequently applying a directional etching process to remove horizontal portions of the conformal layer, resulting in the protective liner 411 at sidewalls of the set of nanosheets 311 of the top nanosheet transistor 310.

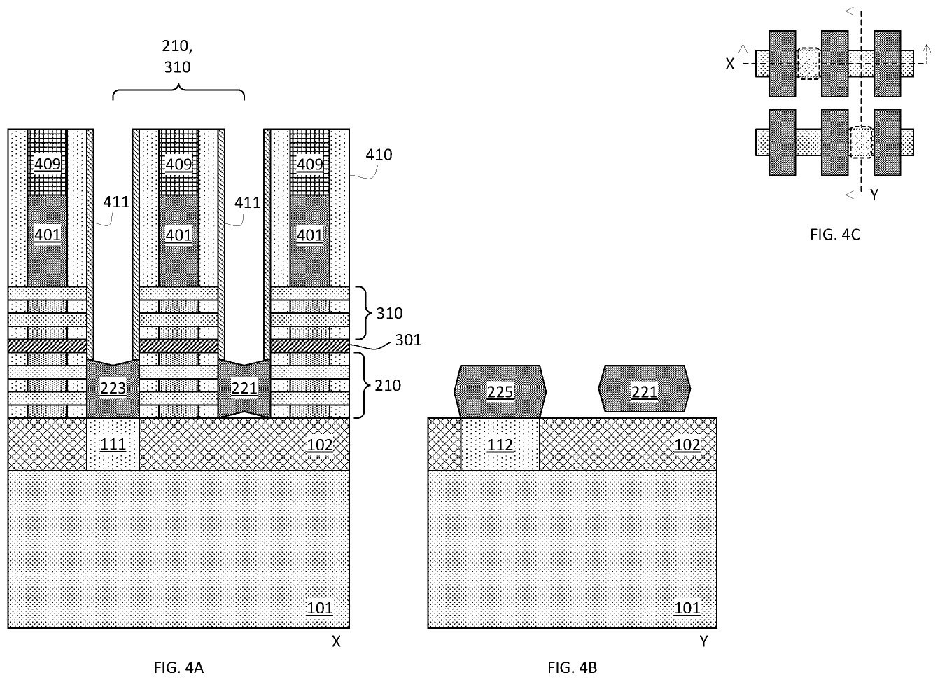

FIGS. 4A and 4B are demonstrative illustrations of different cross-sectional views and FIG. 4C is a simplified top view of a semiconductor structure in a step of manufacturing thereof according to one embodiment of present invention. More particularly, following the step illustrated in FIGS. 3A, 3B, and 3C, embodiments of present invention provide removing the sacrificial layer 201 through, for example, an ash process to expose sidewalls of the set of nanosheets 211 of the bottom nanosheet transistor 210 and the first and the second placeholder 111 and 112 in the oxide layer 102. Next, embodiments of present invention provide forming, by epitaxially growing, source/drain regions of the bottom nanosheet transistor 210 from sidewalls of the set of nanosheets 211, which are Si in material, and from the first and the second placeholder 111 and 112, which are epitaxially grown SiGe.

For example, a first source/drain (S/D) region 221 may be epitaxially grown from sidewalls of the set of nanosheets 211. Because nucleation only happens at the sidewalls of the set of nanosheets 211 but not at the oxide layer 102, growth of the first S/D region 221 may not start from the oxide layer 102, therefore a gap may be formed between the first S/D region 221 and the underneath oxide layer 102. In the meantime, a third S/D region 223 may be epitaxially grown from both sidewalls of the set of nanosheets 211 and from the first placeholder 111, and a fifth S/D region 225 may be epitaxially grown from both sidewalls of the set of nanosheets and from the second placeholder 112.

In one embodiment, the epitaxial growth of the first S/D region 221 may be controlled and timely stopped or terminated when the epitaxial growth from the set of nanosheets 211 at the left side and from the set of nanosheets 211 at the right side start to merge, resulting in a V-shaped top surface, in the cross-section made in a direction along the length of the gate as is illustrated in FIG. 4A, which helps increase the contact area with a S/D contact to be formed thereupon. At the bottom of the first S/D region 221, an inverted V-shaped bottom surface may be formed since there is no epitaxial growth from the oxide layer 102. In the meantime, the third and the fifth S/D regions 223 and 225 may have only a V-shaped top surface since the third and the fifth S/D regions 223 and 225 grow epitaxially from the first and the second placeholders 111 and 112 as well. Thus, unlike the first S/D region 221, bottom surfaces of the third S/D region 223 and the fifth S/D region 225 are in full contact with the first and the second placeholders 111 and 112 respectively.

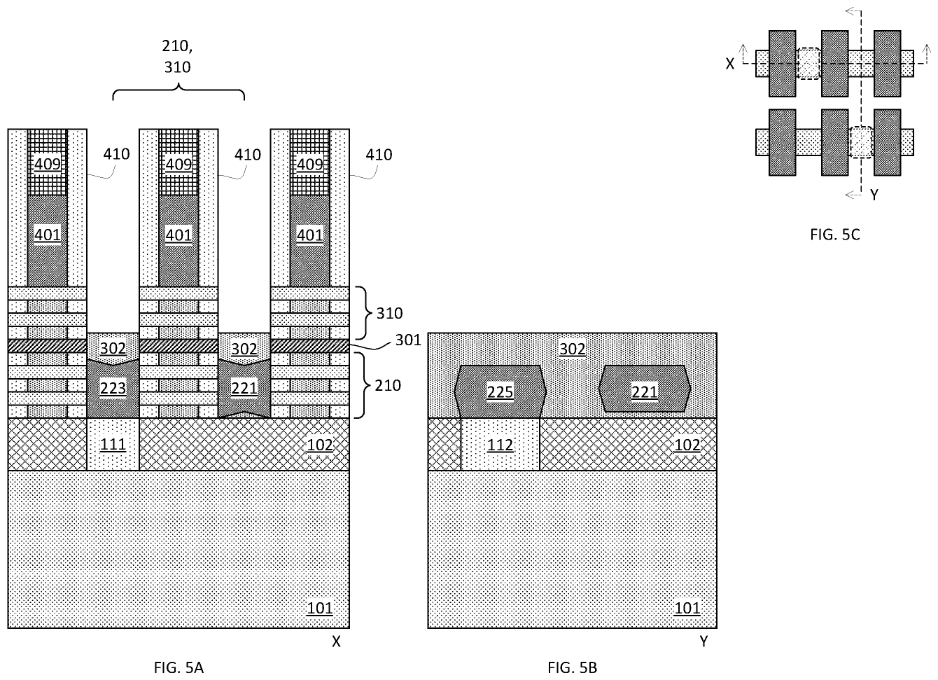

FIGS. 5A and 5B are demonstrative illustrations of different cross-sectional views and FIG. 5C is a simplified top view of a semiconductor structure in a step of manufacturing thereof according to one embodiment of present invention. More particularly, following the step illustrated in FIGS. 4A, 4B, and 4C, embodiments of present invention provide selectively removing the liner 411 to expose the MDI layer 301, and depositing a first interlevel dielectric (ILD) layer 302 covering the formed S/D regions including the first, the third, and the fifth S/D regions 221, 223, and 225. The first ILD layer 302 may be formed, for example, by first depositing a dielectric material in the openings between, and above, the sacrificial gate structures; applying a CMP process to planarize a top surface of the deposited dielectric material; and recessing the dielectric material until sidewalls of the set of nanosheets 311 of the top nanosheet transistor 310 are exposed. The remaining dielectric material forms the first ILD layer 302 that covers sidewalls of the MDI layer 301.

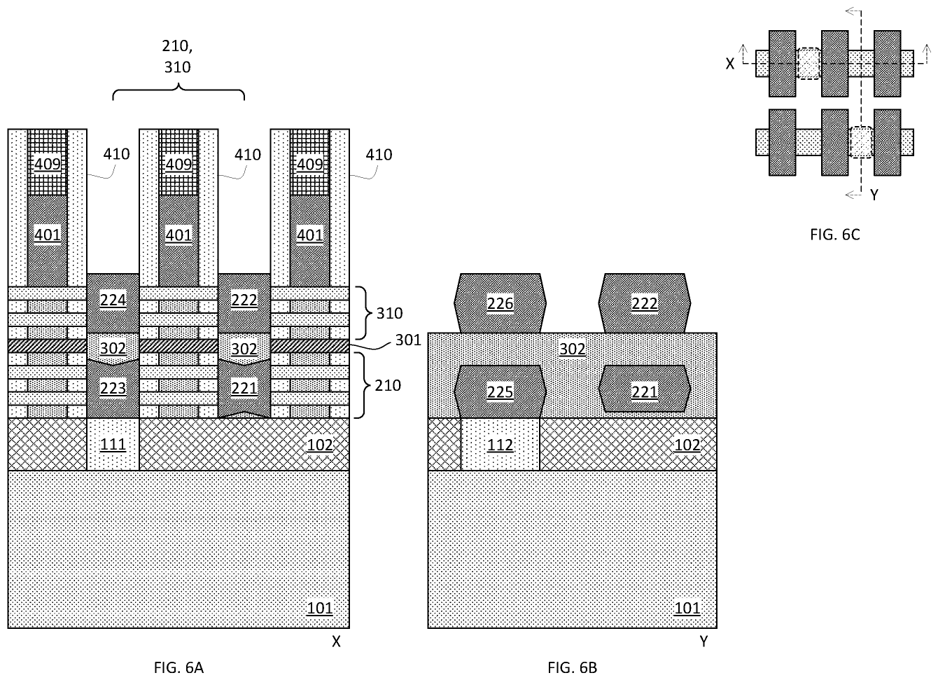

FIGS. 6A and 6B are demonstrative illustrations of different cross-sectional views and FIG. 6C is a simplified top view of a semiconductor structure in a step of manufacturing thereof according to one embodiment of present invention. More particularly, following the step illustrated in FIGS. 5A, 5B, and 5C, embodiments of present invention provide epitaxially growing S/D regions from sidewalls of the set of nanosheets 311 of the top nanosheet transistor 310 above the first ILD layer 302.

For example, a second S/D region 222 and a fourth S/D region 224 of the top nanosheet transistor 310 may be formed, for example through epitaxially grown from sidewalls of the set of nanosheets 311, to be respectively on top of the first S/D region 221 and the third S/D region 223 of the bottom nanosheet transistor 210 via the first ILD layer 302. Additionally, a sixth S/D region 226 may be formed epitaxially on top of the fifth S/D region 225. In one embodiment, and unlike the first S/D region 221, the second, the fourth, and the sixth S/D region 222, 224, and 226 may be overgrown such that their bottom surfaces may be in full contact with the underneath first ILD layer 302.

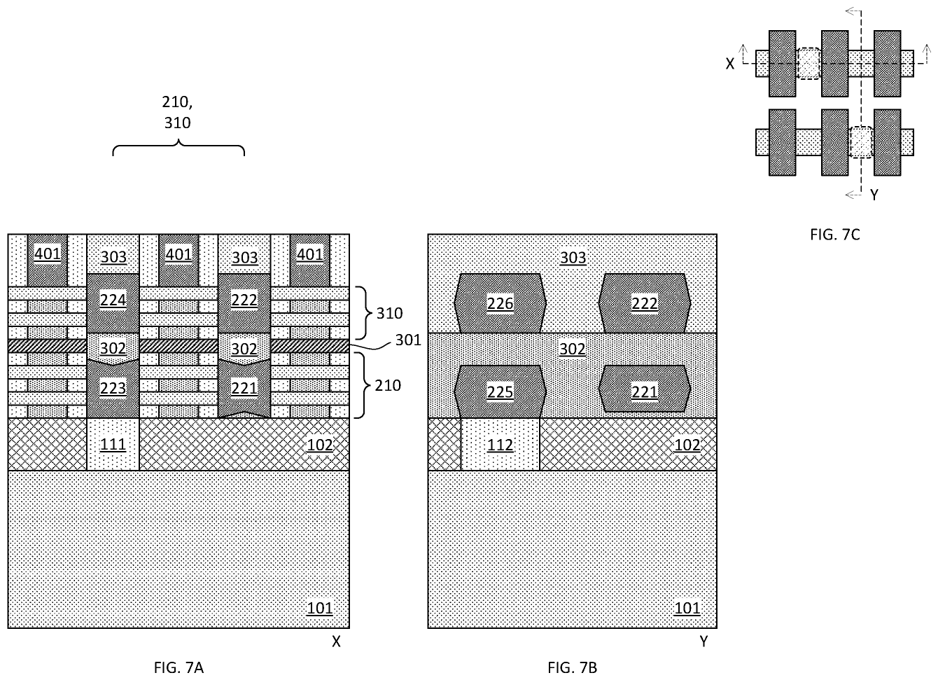

FIGS. 7A and 7B are demonstrative illustrations of different cross-sectional views and FIG. 7C is a simplified top view of a semiconductor structure in a step of manufacturing thereof according to one embodiment of present invention. More particularly, following the step illustrated in FIGS. 6A, 6B, and 6C, embodiments of present invention provide depositing a second interlevel dielectric (ILD) layer 303 covering the second and the fourth S/D regions 222 and 224 of the top nanosheet transistor 310, as well as the sixth S/D region 226. The second ILD layer 303 may be formed, for example, by first depositing a dielectric material in the openings between, and above, the sacrificial gate structures and subsequently applying a CMP process to planarize a top surface of the deposited dielectric material. In one embodiment, the dielectric material of the second ILD layer 303 may be different from the dielectric material of the first ILD layer 302. Additionally, the CMP process may remove the hard masks 409 on top of the sacrificial gates 401 and possibly a portion of the sacrificial gates 401.

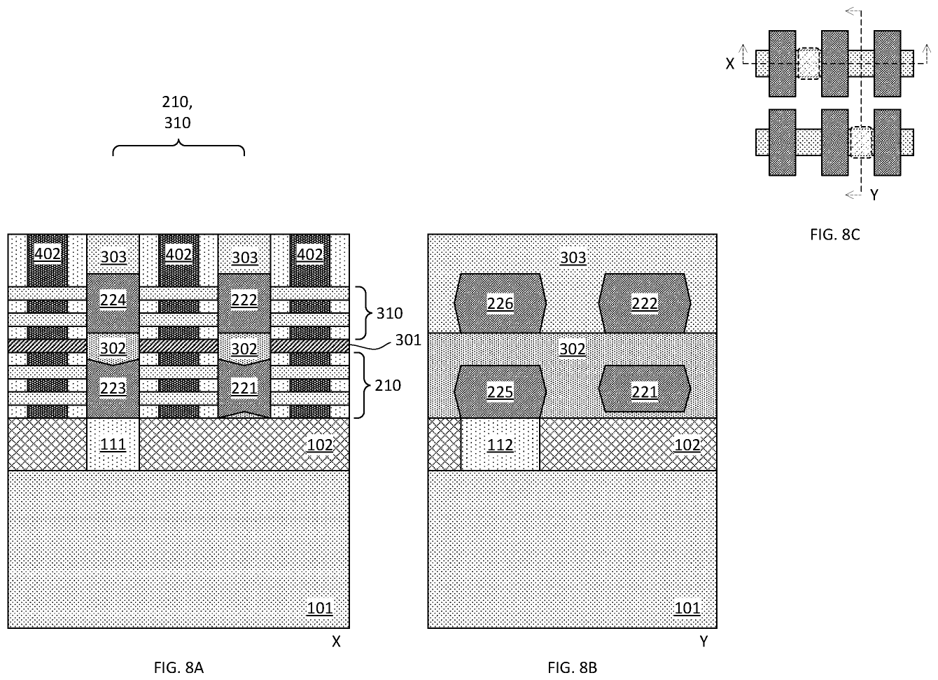

FIGS. 8A and 8B are demonstrative illustrations of different cross-sectional views and FIG. 8C is a simplified top view of a semiconductor structure in a step of manufacturing thereof according to one embodiment of present invention. More particularly, following the step illustrated in FIGS. 7A, 7B, and 7C, embodiments of present invention provide selectively removing the sacrificial gate 401; selectively removing the sacrificial sheets 312 surrounding the set of nanosheets 311 of the top nanosheet transistor 310; and selectively removing the sacrificial sheets 212 surrounding the set of nanosheets 211 of the bottom nanosheet transistor 210. Next, a metal gate 402 may be formed in a replacement-metal-gate (RMG) process where materials of the metal gate 402 may be used to fill the spaces left by the removal of the sacrificial gate 401, the sacrificial sheets 312, and the sacrificial sheets 212. The metal gate 402 may include a layer of gate dielectric, one or more layers of work-function metals, and a gate metal on top of the one or more work-function metals. The gate metal may include, for example, tungsten (W), cobalt (Co), copper (Cu), aluminum (AI), and/or other suitable conductive materials.

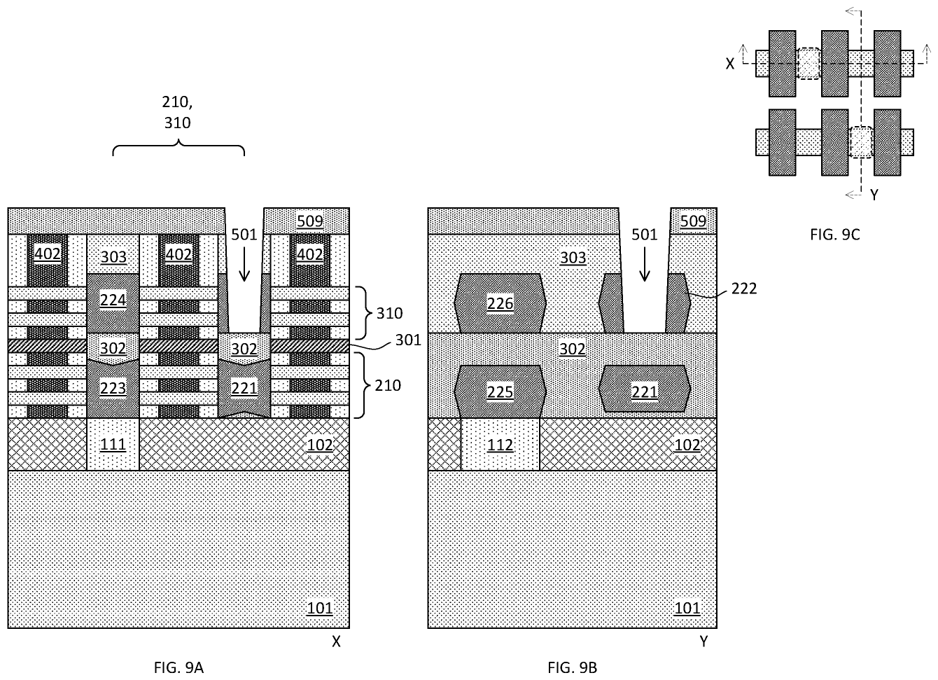

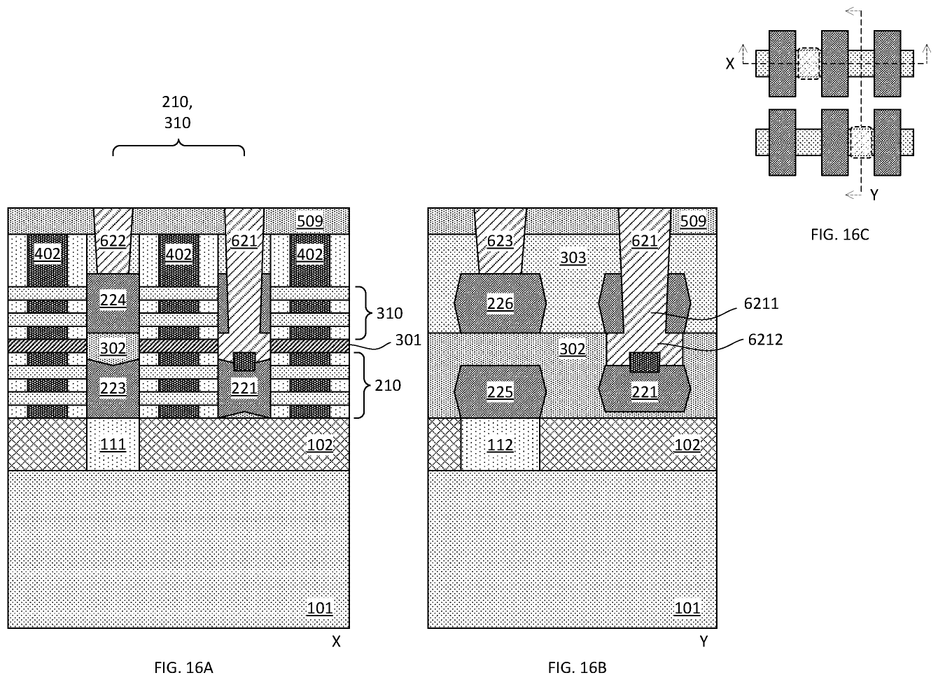

FIGS. 9A and 9B are demonstrative illustrations of different cross-sectional views and FIG. 9C is a simplified top view of a semiconductor structure in a step of manufacturing thereof according to one embodiment of present invention. More particularly, following the step illustrated in FIGS. 8A, 8B, and 8C, embodiments of present invention provide forming one or more source/drain contacts such as, for example, a first S/D contact 621 (see FIGS. 16A, 16B) contacting both the bottom nanosheet transistor 210 and the top nanosheet transistor 310. In forming the first S/D contact 621, embodiments of present invention provide creating an opening 501 in the second S/D region 222 of the top nanosheet transistor 310. The opening 501 may extend from a top surface to a bottom surface of the second S/D region 222 and may be formed by first forming a hard mask 509 with an opening on top of the second ILD layer 303 and subsequently transferring the opening in the hard mask 509 onto the second ILD layer 303 and the second S/D region 222 in a selective and/or directional etching process. The selective etching process may etch through the second S/D region 222 to expose the first ILD layer 302 underneath thereof. The opening 501 may include sidewalls of epitaxial SiGe of the second S/D region 222.

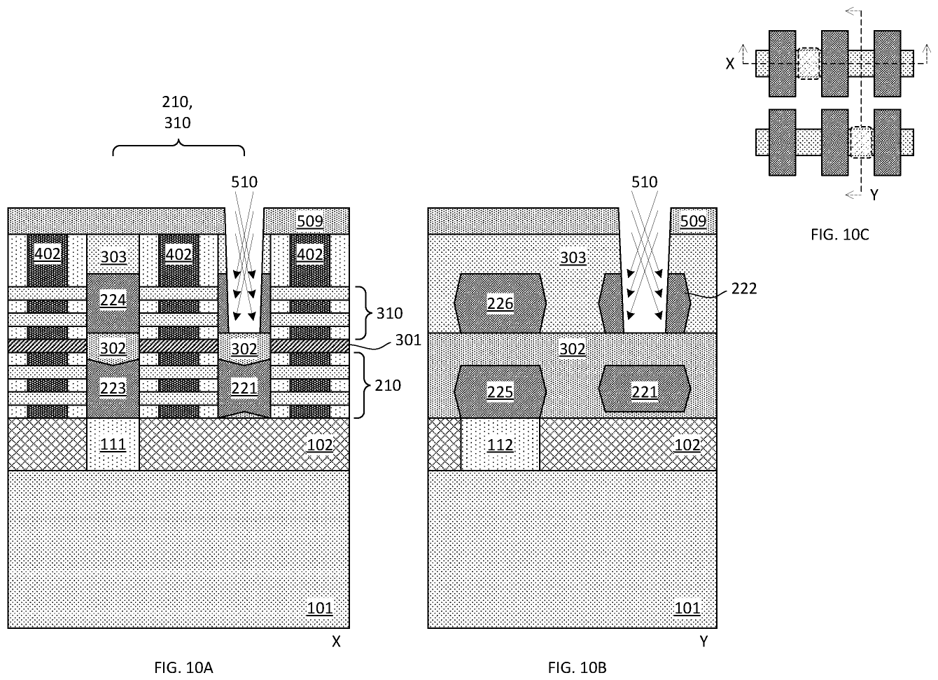

FIGS. 10A and 10B are demonstrative illustrations of different cross-sectional views and FIG. 10C is a simplified top view of a semiconductor structure in a step of manufacturing thereof according to one embodiment of present invention. More particularly, following the step illustrated in FIGS. 9A, 9B, and 9C, embodiments of present invention provide performing ion implantation into the exposed sidewalls of the opening 501 that are part of the second S/D region 222. In other words, ion may be implanted into inner sidewalls of the second S/D region 222. By implanting suitable dopants, such as boron (B) for p-type nanosheet transistor or phosphorus (P) for n-type nanosheet transistor, embodiments of present invention may be able to further enhance conductivity of the second S/D region 222.

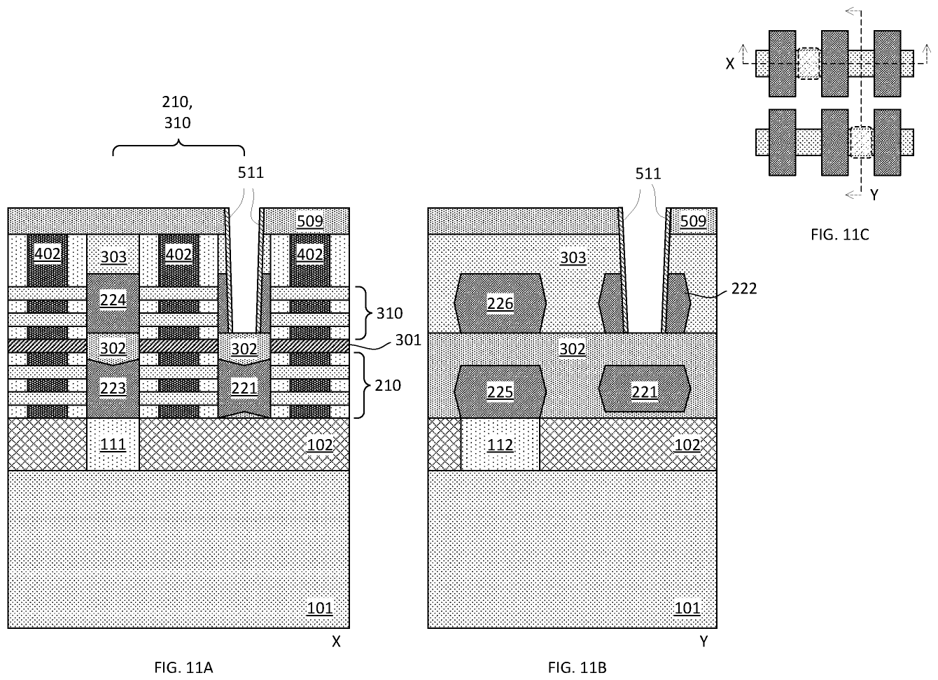

FIGS. 11A and 11B are demonstrative illustrations of different cross-sectional views and FIG. 11C is a simplified top view of a semiconductor structure in a step of manufacturing thereof according to one embodiment of present invention. More particularly, following the step illustrated in FIGS. 10A, 10B, and 10C, embodiments of present invention provide forming a protective liner 511 lining the sidewalls of the opening 501. The protective liner 511 provides protection of the second S/D drain region 222 of the top nanosheet transistor 310 during subsequent etching process which continues to create openings to expose the first S/D region 221 of the bottom nanosheet transistor 210. The protective liner 511 may be formed, for example, by depositing a conformal layer of protective material covering the semiconductor structure 10 and subsequently applying a directional etching process to remove horizontal portions of the conformal layer, resulting in the protective liner 511 at sidewalls of the opening 501 and particularly at the inner sidewalls of the second S/D region 222.

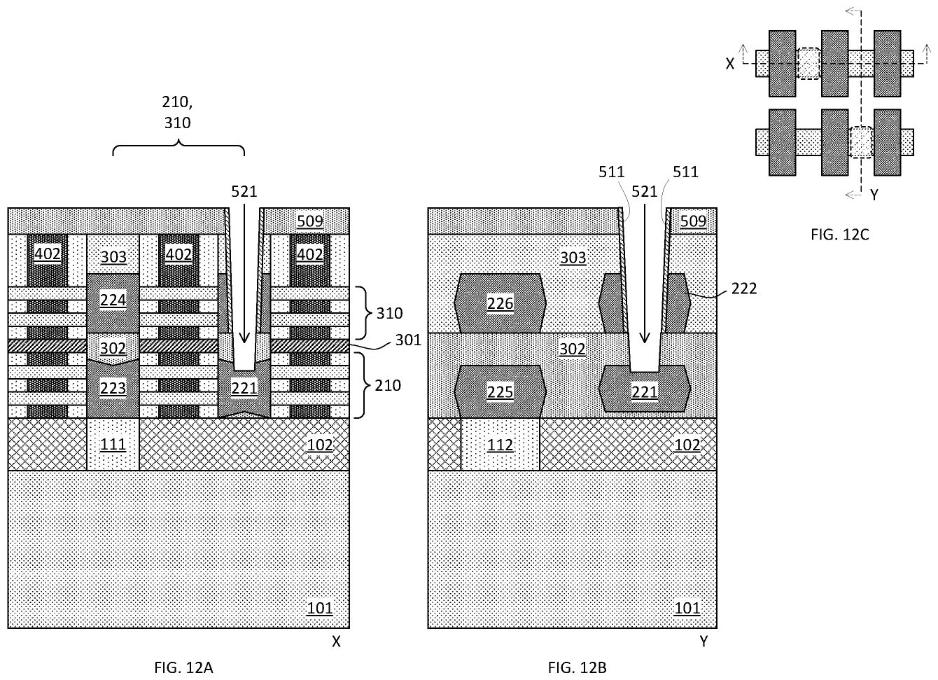

FIGS. 12A and 12B are demonstrative illustrations of different cross-sectional views and FIG. 12C is a simplified top view of a semiconductor structure in a step of manufacturing thereof according to one embodiment of present invention. More particularly, following the step illustrated in FIGS. 11A, 11B, and 11C, embodiments of present invention provide selectively etching, for example through a reactive-ion-etching (RIE) process, the first ILD layer 302 exposed by the opening 501 until at least the top surface of the first S/D region 221 of the bottom nanosheet transistor 210 is exposed. The selective etching may further create an opening 521 below the opening 501 in the first ILD layer 302 and, in one embodiment, the opening 521 may be partially etched into the first S/D region 221 of the bottom nanosheet transistor 210. During the selective etching process in creating the opening 521, the epitaxially grown SiGe of the second S/D region 222 of the top nanosheet transistor 310 is protected by the protective liner 511.

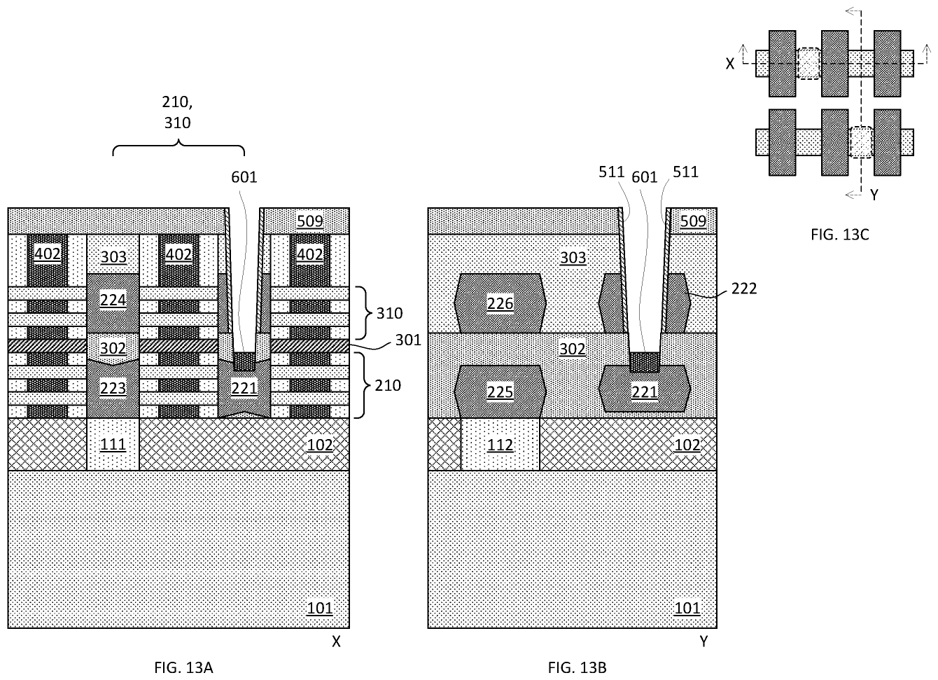

FIGS. 13A and 13B are demonstrative illustrations of different cross-sectional views and FIG. 13C is a simplified top view of a semiconductor structure in a step of manufacturing thereof according to one embodiment of present invention. More particularly, following the step illustrated in FIGS. 12A, 12B, and 12C, embodiments of present invention provide forming a trench epi of a trench anchor 601 in the opening 521 by performing a trench epitaxial growth of, for example, boron doped SiGe for PFET or Phosphorus doped Si for NFET in the opening 521 to form the trench epi. The trench anchor 601 may be grown from the exposed first S/D region 221 of the bottom nanosheet transistor 210 to have a height that is below a bottom surface of the second S/D region 222 of the top nanosheet transistor 310. In other words, a top surface of the trench anchor 601 may be below a top surface of the first ILD layer 302. This is important for enabling a partially wrap around contact formation later for bottom S/D epi with trench epi to achieve low contact resistance.

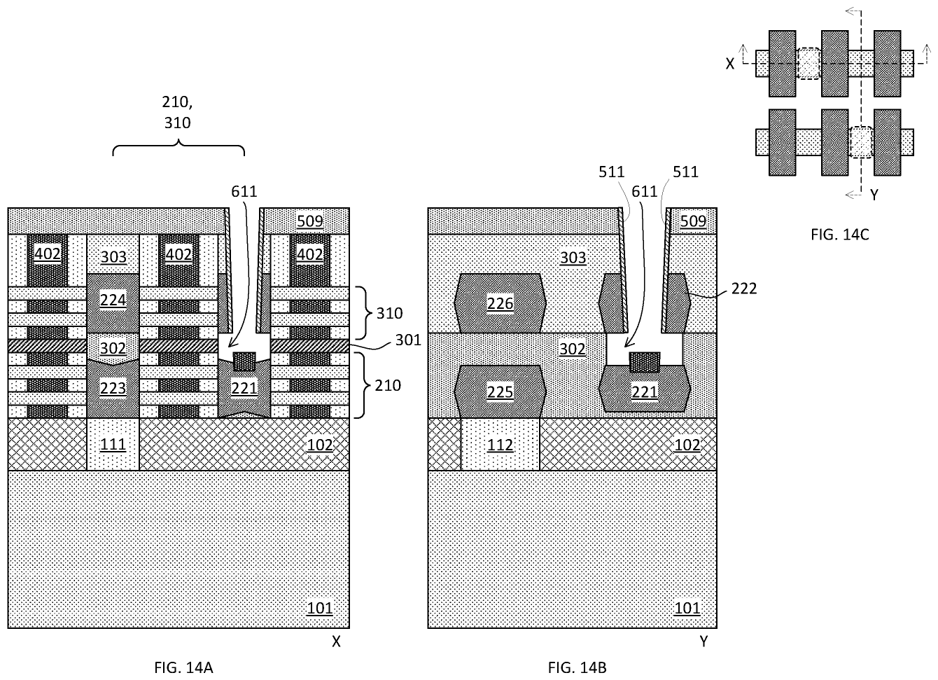

FIGS. 14A and 14B are demonstrative illustrations of different cross-sectional views and FIG. 14C is a simplified top view of a semiconductor structure in a step of manufacturing thereof according to one embodiment of present invention. More particularly, following the step illustrated in FIGS. 13A, 13B, and 13C, embodiments of present invention provide etching the first ILD layer 302, via the openings 501 and 521, selective to the surrounding material including the trench anchor 601, the top surface of the first S/D region 221 of the bottom nanosheet transistor 210, and the bottom surface of the second S/D region 222 of the top nanosheet transistor 310. For example, the etching of the first ILD layer 302 may expand a portion of the openings 501 and 521 to create an opening 611 by enlarging the opening 521 horizontally until both the bottom surface of the second S/D region 222 of the top nanosheet transistor 310 and the top surface of the first S/D region 221 of the bottom nanosheet transistor 210 are substantially exposed. The opening 611 may saddle on the trench anchor 601 of a trench epi. In other words, the opening 611 may have an upside-down U-shape, in a cross-section across the gate in a direction along the length of the gate, as illustrated in FIG. 14A, and in a cross-section across the S/D region in a direction along the width of the gate, as is illustrated in FIG. 14B.

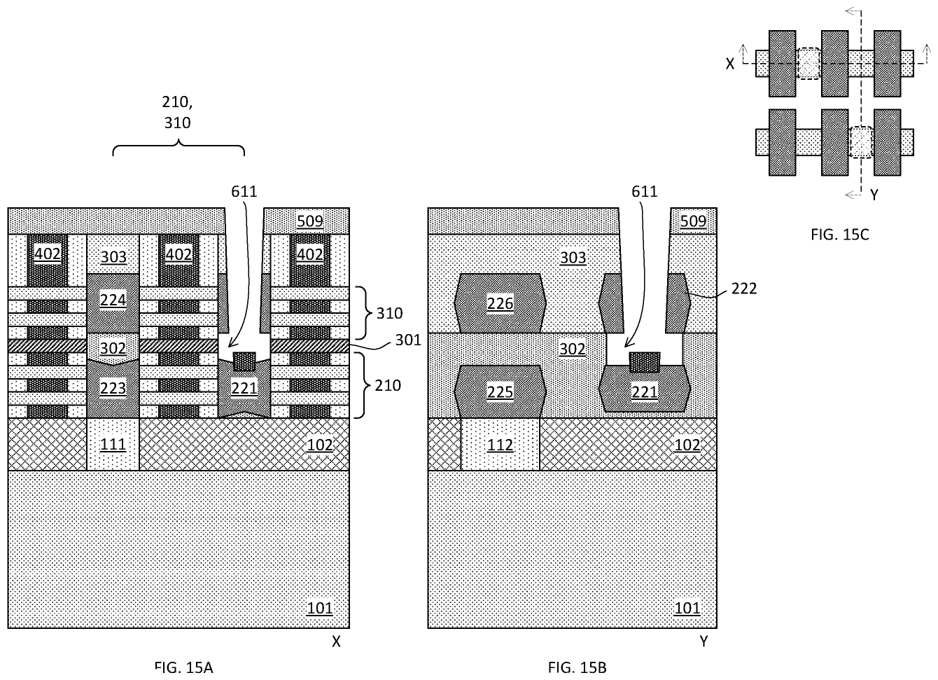

FIGS. 15A and 15B are demonstrative illustrations of different cross-sectional views and FIG. 15C is a simplified top view of a semiconductor structure in a step of manufacturing thereof according to one embodiment of present invention. More particularly, following the step illustrated in FIGS. 14A, 14B, and 14C, embodiments of present invention provide removing the protective liner 511 in a selective etching process to expose inner sidewalls of the second S/D region 222 of the top nanosheet transistor 310. For example, an etching process that provides etch selectivity between silicon-nitride (SiN), such as that of the protective liner 511, and epitaxially grown SiGe, such as those of the trench anchor 601, the first S/D region 221 of the bottom nanosheet transistor 210, and the second S/D region 222 of the top nanosheet transistor 310 may be used to remove the protective liner 511.

FIGS. 16A and 16B are demonstrative illustrations of different cross-sectional views and FIG. 16C is a simplified top view of a semiconductor structure in a step of manufacturing thereof according to one embodiment of present invention. More particularly, following the step illustrated in FIGS. 15A, 15B, and 15C, embodiments of present invention provide creating additional openings in the second ILD layer 303, through the hard mask 509, to expose selective S/D regions of the top nanosheet transistors. For example, in addition to the opening 611, a second opening may be created to expose a top surface of the fourth S/D region 224 of the top nanosheet transistor 310 and a third opening may be created to expose a top surface of the sixth S/D region 226. Conductive materials include a silicide liner, such as Ti, metal adhesion liner such as TiN, and low resistance metal fill such as tungsten (W), copper (Cu), cobalt (Co), ruthenium (Ru) and/or other suitable materials may subsequently be deposited into the openings to create S/D contacts such as a first S/D contact 621, a second S/D contact 622, and a third S/D contact 623.

Particularly, the first S/D contact 621 may be formed to be a shared S/D contact of the top nanosheet transistor 310 and the bottom nanosheet transistor 210 shared by the second S/D region 222 and the first S/D region 221. The first S/D contact 621 may include a top portion 6211 and a bottom portion 6212 directly underneath the top portion 6211. The top portion 6211 of the first S/D contact 621 may contact a portion of the bottom portion 6212 of the first S/D contact 621 and is in full contact with inner sidewalls of the second S/D region 222 of the top nanosheet transistor 310. In the meantime, the bottom portion 6212 of the first S/D contact 621 contacts both the bottom surface of the second S/D region 222 of the top nanosheet transistor 310 and the top surface of the first S/D region 221 of the bottom nanosheet transistor 210, resulting in a substantial increase in contact surfaces of the first S/D contact 621 with the second S/D region 222 of the top nanosheet transistor 310 and the first S/D region 221 of the bottom nanosheet transistor 210. Moreover, the bottom portion 6212 of the first S/D contact 621 saddles on the trench anchor 601, which further increases the contact surfaces between the first S/D contact 621 and the first S/D region 221 of the bottom nanosheet transistor 210, thereby resulting in substantially improved conductivity and reduced resistance that are challenging issues facing the current art.

The second S/D contact 622 may be formed to be in contact with the fourth S/D region 224 of the semiconductor structure 10, and the third S/D contact 623 may be formed to be in contact with the sixth S/D region of the semiconductor structure 10. After depositing the conductive material in the openings to form the various metal contacts, a CMP process may be applied to planarize a top surface of the conductive material thereby finishing forming the first, second, and third metal contacts 621, 622, and 623.

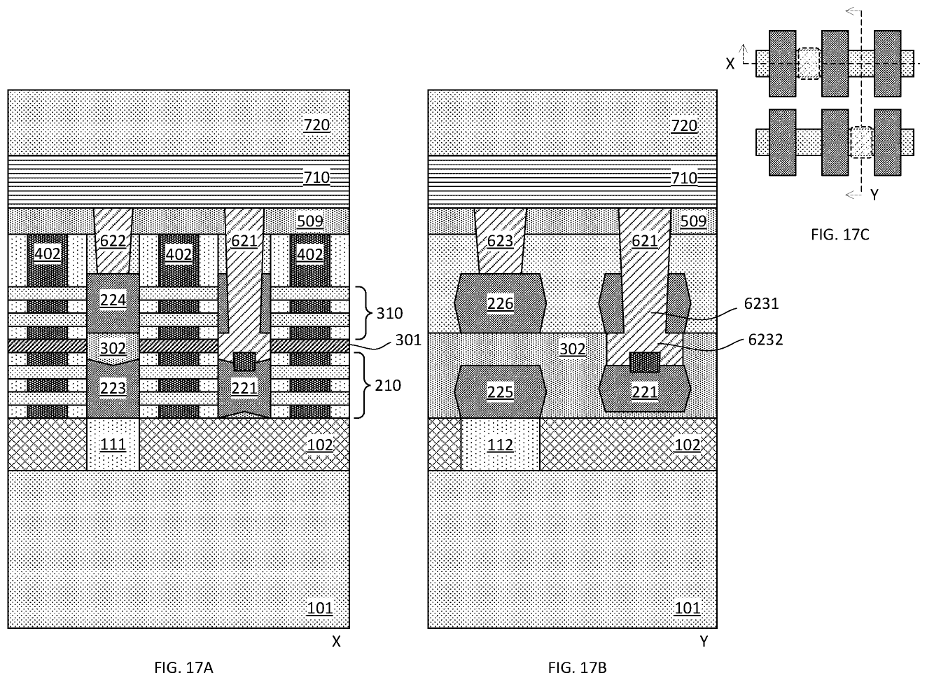

FIGS. 17A and 17B are demonstrative illustrations of different cross-sectional views and FIG. 17C is a simplified top view of a semiconductor structure in a step of manufacturing thereof according to one embodiment of present invention. More particularly, following the step illustrated in FIGS. 16A, 16B, and 16C, embodiments of present invention provide continuing to form a back-end-of-line (BEOL) structure 710 on top of the second ILD layer 303 and on top of the first, second, and third S/D contacts 621, 622, and 623. The BEOL structure 710 may be used to provide signal routing and/or power distribution functions to underneath front-end-of-line (FEOL) devices including, for example, the top nanosheet transistor 310 and the bottom nanosheet transistor 210. Embodiments of present invention further provide bonding a carrier wafer 720 onto the BEOL structure 710 such that the semiconductor structure 10 may be flipped upside-down for further processing from a backside of the semiconductor structure 10 or a backside of the substrate 101.

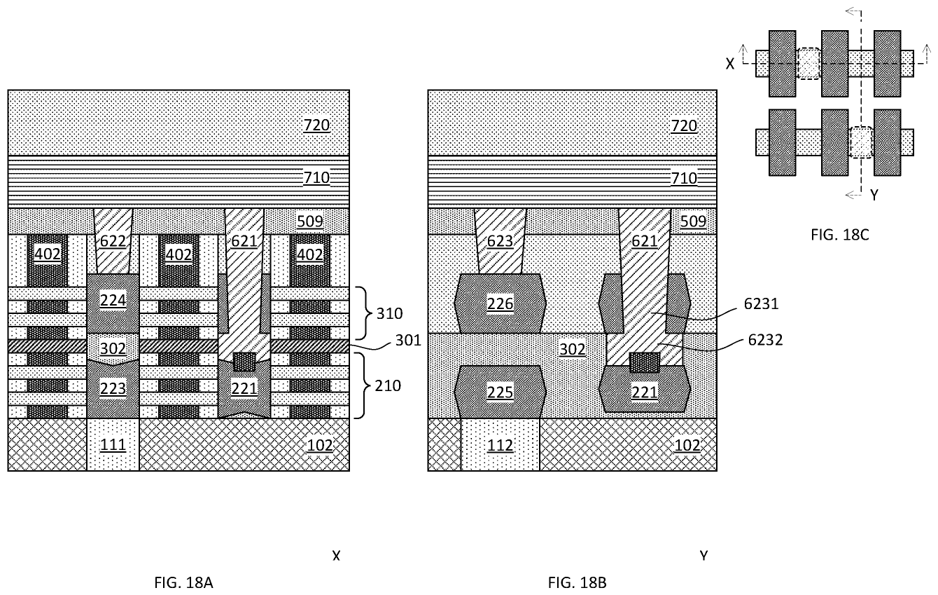

It is to be noted here that upside-up (instead of upside-down) drawings will continue to be used hereinafter, for FIGS. 18A and 18B to FIGS. 20A and 20B, for the ease of illustration. However, description of the drawings may be provided in a manner that is consistent with processing from the backside of the substrate 101.

FIGS. 18A and 18B are demonstrative illustrations of different cross-sectional views and FIG. 18C is a simplified top view of a semiconductor structure in a step of manufacturing thereof according to one embodiment of present invention. More particularly, following the step illustrated in FIGS. 17A, 17B, and 17C, embodiments of present invention provide removing the substrate 101, from the backside of the semiconductor structure 10 through, for example, a grinding process, a CMP process, and/or other selective etching processes. The removal of the substrate 101 may stop at the oxide layer 102 and expose the first and the second placeholder 111 and 112.

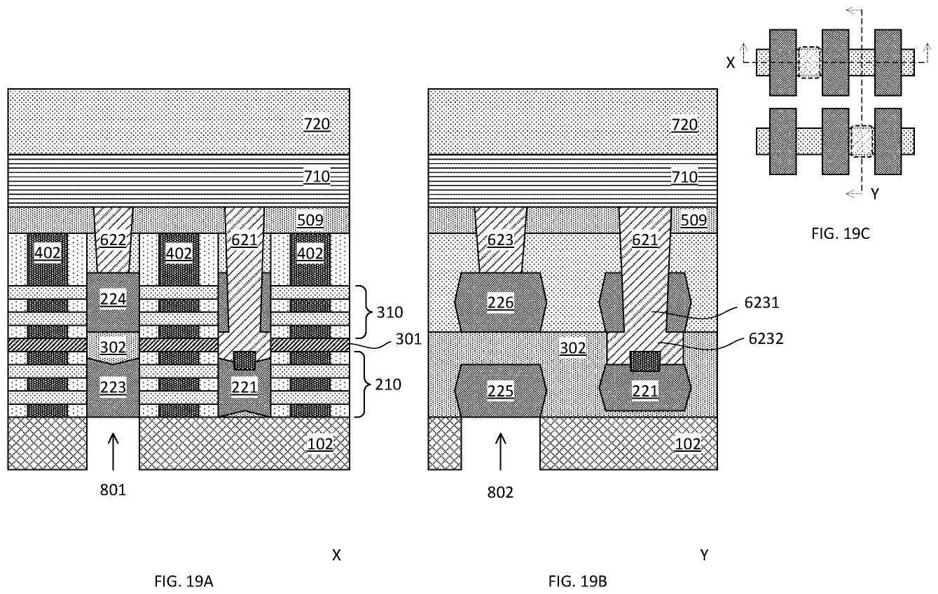

FIGS. 19A and 19B are demonstrative illustrations of different cross-sectional views and FIG. 19C is a simplified top view of a semiconductor structure in a step of manufacturing thereof according to one embodiment of present invention. More particularly, following the step illustrated in FIGS. 18A, 18B, and 18C, embodiments of present invention provide selectively removing the first and the second placeholder 111 and 112 to expose the bottom surfaces of the third S/D region 223 of the first nanosheet transistor 210 and the fifth S/D region 225. The removal of the first and the second placeholder 111 and 112 creates corresponding openings 801 and 802.

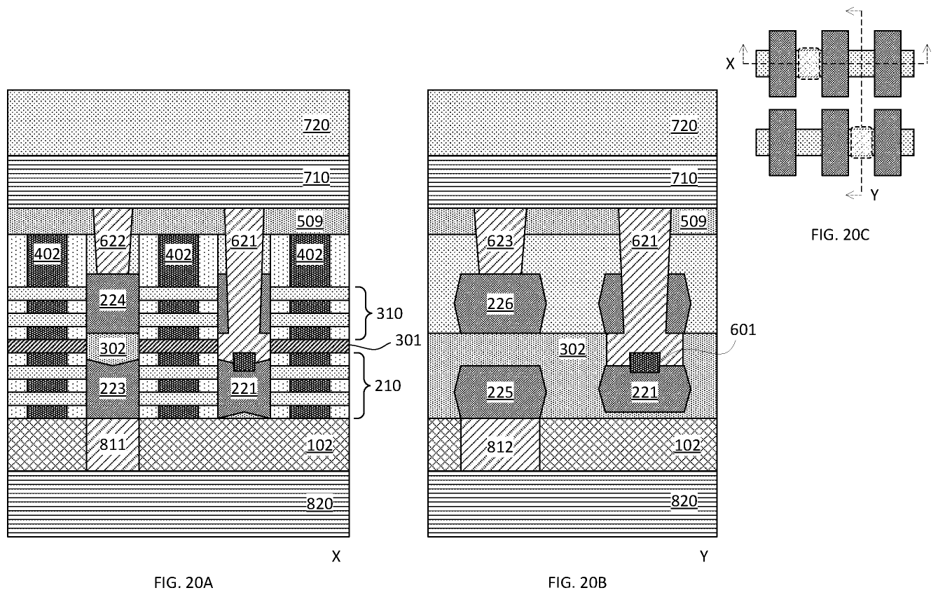

FIGS. 20A and 20B are demonstrative illustrations of different cross-sectional views and FIG. 20C is a simplified top view of a semiconductor structure in a step of manufacturing thereof according to one embodiment of present invention. More particularly, following the step illustrated in FIGS. 19A, 19B, and 19C, embodiments of present invention provide filling the openings 801 and 802 with conductive materials include a silicide liner, such as Ti, metal adhesion liner such as TiN, and low resistance metal fill such as, for example, W, Cu, Co, Ru, and/or other suitable materials to form a first and a second backside S/D contact 811 and 812. A CMP process may subsequently be applied to planarize a top surface of the backside S/D contacts. A backside interconnect structure 820 may then be formed on top of the first and the second backside S/D contact to provide power and/or signal routing functionality.

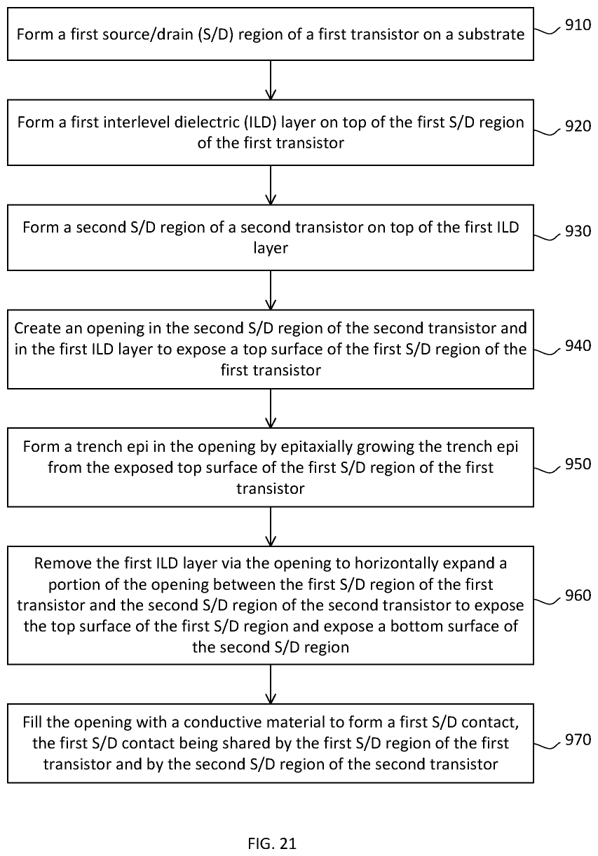

FIG. 21 is a demonstrative illustration of a flow-chart of a method of manufacturing a semiconductor structure according to embodiments of present invention. The method includes (910) forming a first source/drain (S/D) region of a first transistor on a substrate; (920) forming a first interlevel dielectric (ILD) layer on top of the first S/D region; (930) forming a second S/D region of a second transistor on top of the first ILD layer; (940) creating an opening in the second S/D region of the second transistor and in the first ILD layer to expose a top surface of the first S/D region of the first transistor; (950) forming a trench epi in the opening by epitaxially growing the trench epi from the exposed top surface of the first S/D region of the first transistor; (960) removing the first ILD layer via the opening thereby horizontally expanding a portion of the opening between the first S/D region of the first transistor and the second S/D region of the second transistor to expose the top surface of the first S/D region and expose a bottom surface of the second S/D region; and (970) filling the opening with a conductive material to form a first S/D contact, where the first S/D contact is shared by the first S/D region of the first transistor and the second S/D region of the second transistor.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first transistor having a first source/drain (S/D) region;
a second transistor having a second S/D region, the second transistor being stacked on top of the first transistor; and
a first S/D contact shared by the first S/D region of the first transistor and the second S/D region of the second transistor,
wherein the first S/D contact has a first portion and a second portion, the first portion being in direct contact with a top surface of the first S/D region of the first transistor and in direct contact with a bottom surface of the second S/D region, and the second portion being in direct contact with an inner sidewall of the second S/D region of the second transistor.

2. The semiconductor structure of claim 1, further comprising a trench anchor directly on top of the first S/D region of the first transistor, wherein the first portion of the first S/D contact saddles on the trench anchor to be in contact with a top surface and sidewall surfaces of the trench anchor.

3. The semiconductor structure of claim 2, wherein the trench anchor comprises epitaxially grown silicon-germanium (SiGe) and is partially embedded in the first S/D region of the first transistor.

4. The semiconductor structure of claim 1, wherein the second portion of the first S/D contact is directly on top of a portion of the first portion of the first S/D contact.

5. The semiconductor structure of claim 1, wherein the second S/D region of the second transistor includes an opening extending from a top surface thereof to the bottom surface thereof, the opening has the inner sidewall, and the inner sidewall is in direct contact with the second portion of the first S/D contact.

6. The semiconductor structure of claim 1, wherein the first and the second transistor are a first and a second nanosheet transistor, further comprising a dielectric insulating layer separating the first transistor from the second transistor.

7. The semiconductor structure of claim 1, wherein the top surface of the first S/D region of the first transistor has a V-shape and a bottom surface of the first S/D region of the first transistor has an inverted V-shape.

8. The semiconductor structure of claim 1, further comprising a second S/D contact contacting a top surface of a fourth S/D region of the second transistor, and a first backside S/D contact contacting a bottom surface of a third S/D region of the first transistor.

9. A method of forming a semiconductor structure comprising:
forming a first source/drain (S/D) region of a first transistor on a substrate;
forming a first interlevel dielectric (ILD) layer on top of the first S/D region;
forming a second S/D region of a second transistor on top of the first ILD layer;
creating an opening in the second S/D region of the second transistor and in the first ILD layer to expose a top surface of the first S/D region of the first transistor;
removing the first ILD layer via the opening thereby horizontally expanding a portion of the opening between the first S/D region of the first transistor and the second S/D region of the second transistor to expose the top surface of the first S/D region and expose a bottom surface of the second S/D region; and
filling the opening with a conductive material to form a first S/D contact, the first S/D contact being shared by the first S/D region of the first transistor and the second S/D region of the second transistor.

10. The method of claim 9, further comprising, before removing the first ILD layer via the opening, forming a trench anchor in the opening by epitaxially growing the trench anchor from the exposed top surface of the first S/D region of the first transistor.

11. The method of claim 10, wherein the trench anchor has a height below the bottom surface of the second S/D region of the second transistor.

12. The method of claim 11, wherein the first S/D contact has a first portion and a second portion with the second portion being directly on top of the first portion, the first portion of the first S/D contact fills the expanded portion of the opening and saddles on the trench anchor.

13. The method of claim 9, wherein forming the first S/D region comprises epitaxially growing the first S/D region to have the top surface formed in a V-shape.

14. The method of claim 9, further comprising forming a second S/D contact contacting a top surface of a fourth S/D region of the second transistor and forming a first backside S/D contact contacting a bottom surface of a third S/D region of the first transistor.

15. A semiconductor structure comprising:
a first transistor having a first and a second source/drain (S/D) region;
a second transistor having a second and a fourth S/D region, the second transistor being stacked on top of the first transistor and having the second S/D region above the first S/D region of the first transistor and the fourth S/D region above the third S/D region of the first transistor;
a trench anchor directly on top of the first S/D region; and
a first S/D contact shared by the first S/D region and the second S/D region,
wherein the first S/D contact has a first portion and a second portion, the first portion being in direct contact with a top surface of the first S/D region, saddling on the trench anchor, and in direct contact with a bottom surface of the second S/D region, and the second portion being directly on top of a portion of the first portion.

16. The semiconductor structure of claim 15, wherein the trench anchor comprises epitaxially grown silicon-germanium (SiGe) and is partially embedded in the first S/D region of the first transistor.

17. The semiconductor structure of claim 15, wherein the second S/D region of the second transistor includes an opening extending from a top surface thereof to the bottom surface thereof, the opening has an inner sidewall, and the inner sidewall is in direct contact with the second portion of the first S/D contact.

18. The semiconductor structure of claim 15, wherein the first and the second transistor are a first and a second nanosheet transistor, further comprising a dielectric insulating layer between the first transistor and the second transistor.

19. The semiconductor structure of claim 15, wherein the top surface of the first S/D region of the first transistor has a V-shape and a bottom surface of the first S/D region of the first transistor has an inverted V-shape.

20. The semiconductor structure of claim 15, further comprising a second S/D contact contacting a top surface of the fourth S/D region of the second transistor, and a first backside S/D contact contacting a bottom surface of the third S/D region of the first transistor.
